(19) United States
(12) Patent Application Publication
(10) Pub. No.: US 2025/0202448 A1
(43) Pub. Date: Jun. 19, 2025

(54) VARIABLE GAIN AMPLIFIER AND PHASE SHIFTER

(71) Applicant: Mitsubishi Electric Corporation, Tokyo (JP)

(72) Inventors: Akihito Hirai, Tokyo (JP); Yuki TSUKUI, Tokyo (JP)

(73) Assignee: Mitsubishi Electric Corporation, Tokyo (JP)

(21) Appl. No.: 19/068,355

(22) Filed: Mar. 3, 2025

Related U.S. Application Data
(63) Continuation of application No. PCT/JP2022/040574, filed on Oct. 31, 2022.

(51) Int. Cl. H03G 3/30; H03F 3/45; H03G 1/00

(52) U.S. Cl. CPC H03G 3/3036; H03F 3/45174; H03G 1/0023

(57) ABSTRACT

A variable gain amplifier includes a control unit to acquire set gain information related to a setting of a gain, and, on the basis of the set gain information, output a current to a first reference current transistor and a second reference current transistor in such a manner that the sum of the value of a current to the first reference current transistor and the value of a current to the second reference current transistor becomes constant, and output, to a first variable impedance circuit and a second variable impedance circuit, a voltage obtained by multiplying the absolute value of the difference between the value of a current to the first reference current transistor and the value of a current to the second reference current transistor by a coefficient.

### CROSS REFERENCE TO RELATED APPLICATION

This application is a Continuation of PCT International Application No. PCT/JP2022/040574, filed on Oct. 31, 2022, which is hereby expressly incorporated by reference into the present application.

### TECHNICAL FIELD

The present disclosure relates to a variable gain amplifier and a phase shifter.

### BACKGROUND ART

Typically, semiconductor integrated circuits that process high-frequency signals are used in systems that treat high-frequency signals for communication, radars, and the like. Among such semiconductor integrated circuits, variable gain amplifiers and vector-synthesis-type phase shifters are used for the purpose of adjusting the amplitude of an input signal to a predetermined level. There is a conventionally known variable gain amplifier that can change the size of a transistor depending on changes of the gain when adjusting the amplitude (see Patent Literature 1).

### CITATION LIST

### Patent Literature

Patent Literature 1: JP 1991-190310 A

### SUMMARY OF INVENTION

### Technical Problem

Typically, in a variable gain amplifier, the capacitance of an equivalent input or output changes when a gain is changed; as a result, a passing phase changes depending on changes of the gain, undesirably. Because of this, a variable gain amplifier and a phase shifter that can reduce changes of a passing phase at the time when a gain is changed have been demanded.

The present disclosure solves the problem described above, and an object thereof is to provide a variable gain amplifier and a phase shifter that can reduce changes of a passing phase at the time when a gain is changed.

### Solution to Problem

A variable gain amplifier according to the present disclosure includes: a first input terminal; a second input terminal; a power supply terminal; a ground terminal; a first variable impedance circuit connected between the first input terminal and the ground terminal; a second variable impedance circuit connected between the second input terminal and the ground terminal; a first transistor having a base terminal that is connected to the first input terminal, and having an emitter terminal connected to the ground terminal; a second transistor having a base terminal that is connected to the second input terminal, having an emitter terminal that is connected to the ground terminal, and having a collector terminal that is connected to a collector terminal of the first transistor; a third transistor having a base terminal that is connected to the first input terminal, and having an emitter terminal that is connected to the ground terminal; a fourth transistor having a base terminal that is connected to the second input terminal, having an emitter terminal that is connected to the ground terminal, and having a collector terminal that is connected to a collector terminal of the third transistor; a first reference current transistor that is diode-connected, and is connected to the first transistor and the fourth transistor in such a manner that the first transistor and the fourth transistor form a current mirror; a second reference current transistor that is diode-connected, and is connected to the second transistor and the third transistor in such a manner that the second transistor and the third transistor form a current mirror; a first load connected between both of the collector terminal of the first transistor and the collector terminal of the second transistor and the power supply terminal; a second load connected between both of the collector terminal of the third transistor and the collector terminal of the fourth transistor and the power supply terminal; a first output terminal connected to the first load; a second output terminal connected to the second load; and processing circuitry to acquire set gain information related to a setting of a gain, and, on a basis of the set gain information, output a current to the first reference current transistor and the second reference current transistor in such a manner that a sum of a value of a current to the first reference current transistor and a value of a current to the second reference current transistor becomes constant, and output, to the first variable impedance circuit and the second variable impedance circuit, a voltage obtained by multiplying an absolute value of a difference between a value of a current to the first reference current transistor and a value of a current to the second reference current transistor by a coefficient, wherein, on a basis of reception of an input of an in-phase signal by the first input terminal and reception of an input of an antiphase signal of the in-phase signal by the second input terminal, an in-phase signal amplified on a basis of the set gain information is output from the first output terminal, and an antiphase signal amplified on a basis of the set gain information is output from the second output terminal.

### Advantageous Effects of Invention

The present disclosure makes it possible to reduce changes of a passing phase at the time when a gain is changed.

### BRIEF DESCRIPTION OF DRAWINGS

FIG. 1 is a circuit diagram illustrating a variable gain amplifier according to a first embodiment.

FIG. 2 is an equivalent circuit diagram of transistors included in the variable gain amplifier according to the first embodiment.

FIG. 3 is a circuit diagram illustrating a variable gain amplifier according to a second embodiment.

FIG. 4 is a circuit diagram illustrating a variable gain amplifier according to a third embodiment.

FIG. 5 is a circuit diagram illustrating a variable gain amplifier according to a fourth embodiment.

FIG. 6 is a circuit diagram illustrating a variable gain amplifier according to a fifth embodiment.

FIG. 7 is a circuit diagram illustrating a phase shifter according to a sixth embodiment.

FIG. 8 is a block diagram illustrating an example of the hardware configuration of a control unit.

FIG. 9 is a block diagram illustrating an example of the hardware configuration of the control unit.

### DESCRIPTION OF EMBODIMENTS

Hereinafter, embodiments according to the present disclosure are explained in detail with reference to the figures.

### First Embodiment

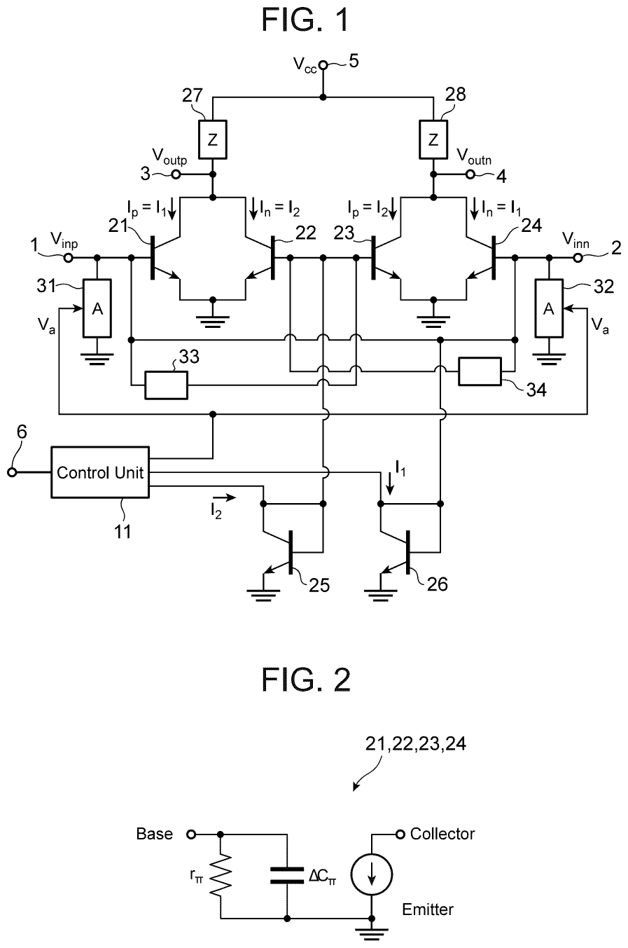

First, a variable gain amplifier according to a first embodiment is explained with reference to FIG. 1 and FIG. 2. FIG. 1 is a circuit diagram illustrating the variable gain amplifier according to the first embodiment. As illustrated in FIG. 1, the variable gain amplifier according to the first embodiment includes a Radio Frequency (RF) signal in-phase input terminal 1, an RF signal antiphase input terminal 2, an RF signal in-phase output terminal 3, an RF signal antiphase output terminal 4, a power supply terminal 5 connected to an AC power supply (not illustrated), an amplitude control signal input terminal 6, a control unit 11, transistors 21, 22, 23, 24, 25, and 26, loads 27 and 28, variable impedance elements 31 and 32, and coupling elements 33 and 34.

The RF signal in-phase input terminal 1 as the first input terminal receives an input of an in-phase signal, for example an RF in-phase signal. The RF signal antiphase input terminal 2 as the second input terminal receives an input of an antiphase signal of the signal input to the RF signal in-phase input terminal 1, for example an RF antiphase signal. The variable impedance element 31 as the first variable impedance circuit is connected between the RF signal in-phase input terminal 1 and a ground terminal. The variable impedance element 32 as the second variable impedance circuit is connected between the RF signal antiphase input terminal 2 and the ground terminal. For example, the variable impedance elements 31 and 32 have only imaginary part components ΔA(Vₐ), and can change only the values of imaginary parts on the basis of an input voltage Vₐ.

For example, the transistors 21 to 26 include bipolar transistors having base (gate) terminals, emitter (source) terminals, and collector (drain) terminals. The transistor 21 as the first transistor has a base terminal that is connected with the RF signal in-phase input terminal 1, and has a grounded emitter terminal. The transistor 22 as the second transistor has a base terminal connected with the RF signal antiphase input terminal 2, and has a grounded emitter terminal. The collector terminal of the transistor 21 and the collector terminal of the transistor 22 are connected to be short-circuited. In addition, the transistor 21 and the transistor 22 form a first transistor pair.

The transistor 23 as the third transistor has a base terminal connected with the RF signal in-phase input terminal 1, and has a grounded emitter terminal. The transistor 24 as the fourth transistor has a base terminal connected with the RF signal antiphase input terminal 2, and has a grounded emitter terminal. The collector terminal of the transistor 23 and the collector terminal of the transistor 24 are connected to be short-circuited. In addition, the transistor 23 and the transistor 24 form a second transistor pair.

The transistor 26 as the first reference current transistor has a collector terminal and a base terminal that are connected with each other. In other words, the transistor 26 is diode-connected. In addition, the transistor 26 is connected with the transistor 21 and the transistor 24 in such a manner that the transistor 21 and the transistor 24 form a current mirror. In other words, in such a manner that a transistor that receives an input of an in-phase signal in the transistors forming the first transistor pair, and a transistor that receives an input of an antiphase signal in the transistors forming the second transistor pair form a current mirror, the transistor 26 is connected with those two transistors. The transistor 26 converts a voltage on the basis of a current I₁ input from the control unit 11, and transmits the converted voltage to the transistors 21 and 24. The current I₁ as a bias current flows through the transistors 21 and 24.

The transistor 25 as the second reference current transistor has a collector terminal and a base terminal that are connected with each other. In other words, the transistor 25 is diode-connected. In addition, the transistor 25 is connected with the transistor 22 and the transistor 23 in such a manner that the transistor 22 and the transistor 23 form a current mirror. In other words, in such a manner that a transistor that receives an input of an antiphase signal in the transistors forming the first transistor pair, and a transistor that receives an input of an in-phase signal in the transistors forming the second transistor pair form a current mirror, the transistor 25 is connected with those two transistors. The transistor 25 converts a voltage on the basis of a current I₂ input from the control unit 11, and transmits the converted voltage to the transistors 22 and 23. The current I₂ as a bias current flows through the transistors 22 and 23.

The loads 27 and 28 have an impedance Z. The load 27 as the first load is connected between both of the collector terminal of the transistor 21 and the collector terminal of the transistor 22 and the power supply terminal 5. In addition, the RF signal in-phase output terminal 3 as the first output terminal is connected between both of the collector terminal of the transistor 21 and the collector terminal of the transistor 22 and the load 27. The load 28 as the second load is connected between both of the collector terminal of the transistor 23 and the collector terminal of the transistor 24 and the power supply terminal 5. In addition, the RF signal antiphase output terminal 4 as the second output terminal is connected between both of the collector terminal of the transistor 23 and the collector terminal of the transistor 24 and the load 28.

The coupling element 33 is connected between the RF signal in-phase input terminal 1 and the base terminal of the transistor 23. The coupling element 34 is connected between the RF signal antiphase input terminal 2 and the base terminal of the transistor 22. An in-phase signal input from the RF signal in-phase input terminal 1 is transmitted to the transistor 21, transmitted to the variable impedance element 31, and transmitted to the transistor 23 via the coupling element 33. An antiphase signal input from the RF signal antiphase input terminal 2 is transmitted to the transistor 24, transmitted to the variable impedance element 32, and transmitted to the transistor 22 via the coupling element 34. The coupling elements 33 and 34 have functions to block DC components, and transmit only AC components.

The control unit 11 acquires set gain information input from the amplitude control signal input terminal 6, and, on the basis of the acquired set gain information, outputs the current I₁ to the transistor 26, and outputs the current I₂ to the transistor 25. In addition, the control unit 11 supplies a control voltage Vₐ to the variable impedance elements 31 and 32 on the basis of the acquired set gain information. The set gain information is information about settings of a gain of the variable gain amplifier (gain settings). For example, the set gain information is information for deciding the gain of signal amplification by the variable gain amplifier. In addition, for example, the set gain information is set amplitude information for deciding the amplitude of a signal output from the variable gain amplifier.

FIG. 2 is an equivalent circuit diagram of the transistors 21 to 24 included in the variable gain amplifier according to the first embodiment. Assuming that an in-phase input voltage of the variable gain amplifier input from the RF signal in-phase input terminal 1 is Vinp, an antiphase input voltage of the variable gain amplifier input from the RF signal antiphase input terminal 2 is Vinn, an in-phase output voltage of the variable gain amplifier output from the RF signal in-phase output terminal 3 is Voutp, an antiphase output voltage of the variable gain amplifier output from the RF signal antiphase output terminal 4 is Voutn, and the transistors 21 to 24 are represented by the equivalent circuit illustrated in FIG. 2, the ratio of a differential output voltage Voutp-Voutn to a differential input voltage Vinp-Vinn at this time, that is, a differential voltage gain G, is represented by the following Formula (1).

$$G ( {I}_{p} − {I}_{n} , {V}_{a} ) = − \frac{2 Zq}{k T} ( {I}_{1} − {I}_{2} ) \cdot \frac{\frac{2}{{r}_{π}} − j ω ( {C}_{π} ( 0 ) )}{\frac{4}{{r}_{π}} + j ω Δ {C}_{i n} ( \vert {I}_{1} − {I}_{2} \vert , {V}_{a} )} \qquad ( 1 )$$

Note that ΔCᵢₙ represents an amount of change of a parasitic capacitance component of the transistors corresponding to the state of the gain settings, and r_{π} represents a parasitic parallel resistance of the transistors.

Here, k and q are constants, and T is the temperature. In this manner, the circuit makes it possible to adjust a gain using the current difference between I₁ and I₂ output from the control unit 11. Note that the gain is determined by |I₁−I₂|, which is the absolute value of I₁−I₂, and the polarity is determined by the sign of I₁−I₂. In addition, the control unit 11 outputs currents to the transistors 25 and 26 in such a manner that the sum of the currents output to the transistors 25 and 26 becomes constant (I₁+I₂=constant). Here, as illustrated by the following Formula (2), ΔCᵢₙ (|I₁−I₂|, Vₐ) is the sum of a component ΔC_{π}(|Iₚ−Iₙ|) which is a parasitic component of the transistors, and changes on the basis of a bias current difference corresponding to the state of the gain settings, and the imaginary part component ΔA(Vₐ) of the variable impedance elements 31 and 32.

$$Δ {C}_{in} ( \vert {I}_{1} − {I}_{2} \vert , {V}_{a} ) = Δ {C}_{π} ( \vert {I}_{1} − {I}_{2} \vert ) + Δ A ( {V}_{a} ) \qquad ( 2 )$$

In addition, assuming that Z of the loads 27 and 28 includes only a real part, a passing phase change Δϕ at the time when the control unit 11 changes the bias current I₁ and the current I₂ on the basis of the set gain information is represented by the following Formula (3).

$$Δφ = - {tan}^{- 1} \frac{ωΔ {C}_{in} ( \vert {I}_{1} - {I}_{2} \vert , {V}_{a} ) {r}_{π}}{4} \qquad ( 3 )$$

In this manner, the passing phase changes since the differential current is changed on the basis of the gain settings. Here, ΔC_{π}(|I₁−I₂|) can be represented by the following Formula (4) by approximation assuming that the base storage capacitance of the bipolar transistors is a dominant factor. Here, IF is a value called base transit time that is determined dependent on the technology of the bipolar transistors, and, for example, assumes a value from 10 to 500 [ps].

$$Δ {C}_{π} ( \vert {I}_{1} - {I}_{2} \vert ) = {τ}_{F} \frac{q Δ ( \vert {I}_{1} - {I}_{2} \vert )}{k T} \qquad ( 4 )$$

Here, by the control unit 11 changing the variable impedance elements 31 and 32 using reverse characteristics on the basis of the absolute value of the bias current difference as illustrated by the following Formula (5), it is possible to make ΔCᵢₙ (|Iₚ−Iₙ|, Vₐ), which is ΔC_{π}(|I₁−I₂|) and ΔA(Vₐ), zero independently of the state of the gain settings, and it is possible to keep the passing phase constant.

$$Δ A ( {V}_{a} ) = - {τ}_{F} \frac{q Δ ( \vert {I}_{1} - {I}_{2} \vert )}{k T} \qquad ( 5 )$$

Here, the output voltage Vₐ from the control unit 11 is represented by the following Formula (6) using the current difference I₁−I₂.

$${V}_{a} = Δ {A}^{- 1} ( - {τ}_{F} \frac{q Δ ( \vert {I}_{1} - {I}_{2} \vert )}{kT} ) \qquad ( 6 )$$

In this manner, the control unit 11 outputs, to the variable impedance elements 31 and 32, the voltage Va obtained by multiplying the absolute value of the difference between the value of the current I₁ to the transistor 26 and the value of the current I₂ to the transistor 25 by a coefficient.

Note that, here, by setting the currents I₁ and I₂ output from the control unit 11 as illustrated by the following Formula (7), it is possible to cancel temperature characteristics of the gain G, ΔC_{π}(|I₁−I₂|), and ΔA(Vₐ), and it is possible to obtain the constant passing phase independently of gain changes and temperature changes.

$${I}_{1} = A \cdot Δ ( \vert {I}_{1} - {I}_{2} \vert ) \frac{k T}{q} {I}_{2} = ( 1 - A ) \cdot Δ ( \vert {I}_{1} - {I}_{2} \vert ) \frac{kT}{q} \qquad ( 7 )$$

As mentioned above, the variable gain amplifier according to the first embodiment is a variable gain differential amplifier that makes the total amount of currents of transistors constant, changes the in-phase/antiphase current distribution, and controls a gain using a current difference. By using the control unit 11 to change variable impedance elements installed on the input side on the basis of the absolute value of the in-phase/antiphase current distribution using reverse characteristics, it is possible to keep the imaginary part of the input impedance constant, and also it is possible to cancel temperature characteristics. Thereby, the variable gain amplifier according to the first embodiment can reduce changes of the passing phase at the time when a gain is changed, and also can reduce changes of the passing phase when temperature has changed.

In addition, typically, the passing phase/amplitude output from each of elements of a phased array antenna at the time of beamforming needs to be set to a predetermined value. However, in a case where the passing phase changes depending on a gain, passing phase changes of the variable gain amplifier also need to be guaranteed in addition to the passing phase value of a phase shifter. Because of this, there is a problem about phased array antennas that a setting value table of set phases and set amplitudes based on the direction of beamforming and excitation distribution need to be read out for each setting, and the scale of a device increases, undesirably. The variable gain amplifier according to the first embodiment can reduce changes of the passing phase at the time when a gain is changed. Accordingly, as compared to conventional techniques, it is possible to reduce the size of a device such as a phased array antenna for which the variable gain amplifier is used.

In addition, there is a problem about conventional variable gain devices that, because gain characteristics change significantly depending on temperature changes, temperature compensation tables for the passing phases are additionally necessary, and the configurations of devices such as variable gain devices, phase shifters, or phased array antennas become large, undesirably. Since the variable gain amplifier according to the first embodiment can reduce changes of the passing phase at the time when temperature has changed, it is possible to reduce the size of a device.

### Second Embodiment

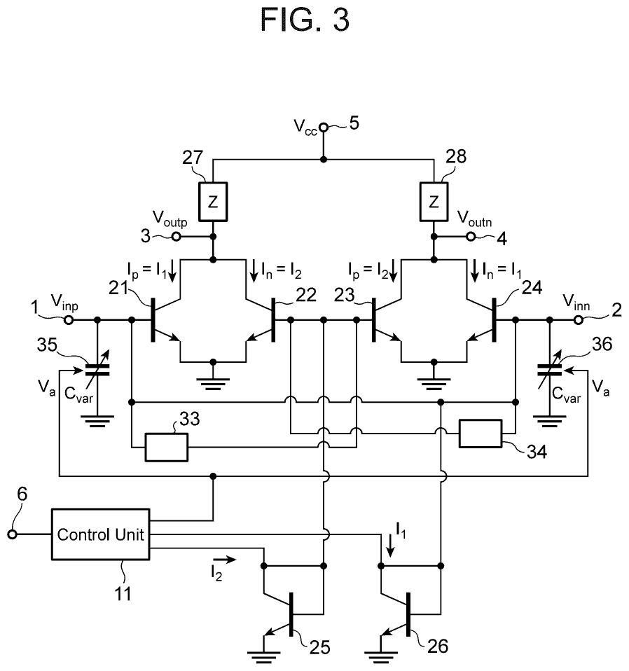

Next, a variable gain amplifier according to a second embodiment is explained with reference to FIG. 3. The variable gain amplifier according to the second embodiment is different from the variable gain amplifier according to the first embodiment in that the variable gain amplifier according to the second embodiment uses varactor elements as variable impedance circuits. Other components in the variable gain amplifier according to the second embodiment are similar, the components that are similar to those in the first embodiment are given identical reference signs, and explanations thereof are omitted.

FIG. 3 is a circuit diagram illustrating the variable gain amplifier according to the second embodiment. As illustrated in FIG. 3, instead of the variable impedance elements 31 and 32 of the variable gain amplifier according to the first embodiment, the variable gain amplifier according to the second embodiment uses varactor elements 35 and 36 as variable impedance circuits. Assuming that an amount of change due to Vₐ of the varactor elements 35 and 36 that are arranged in parallel with the loads 27 and 28 is ΔCᵥₐᵣ, it is possible to keep the input impedance constant, and it is possible to keep the passing phase constant by giving a capacitance change to a voltage as illustrated in the following Formula (8).

$$Δ {C}_{var} ( {V}_{a} ) = - {τ}_{F} \frac{q Δ ( \vert {I}_{1} - {I}_{2} \vert )}{k T} \qquad ( 8 )$$

At this time, a control unit 11 outputs the output voltage Vₐ as illustrated in the following Formula (9) for the current difference I₁−I₂.

$${V}_{a} = Δ {C}_{var}^{- 1} ( - {τ}_{F} \frac{q Δ ( \vert {I}_{1} - {I}_{2} \vert )}{k T} ) \qquad ( 9 )$$

As mentioned above, the variable gain amplifier according to the second embodiment is a variable gain differential amplifier that changes the in-phase/antiphase current distribution, and controls a gain using a current difference. By using the control unit 11 to change varactor capacitances installed on the input side on the basis of the absolute value of the in-phase/antiphase current distribution using reverse characteristics, it is possible to keep the imaginary part of the input impedance constant, and also it is possible to cancel temperature characteristics. Thereby, it is possible to reduce changes of the passing phase at the time when a gain is changed, and also to reduce changes of the passing phase when temperature has changed.

### Third Embodiment

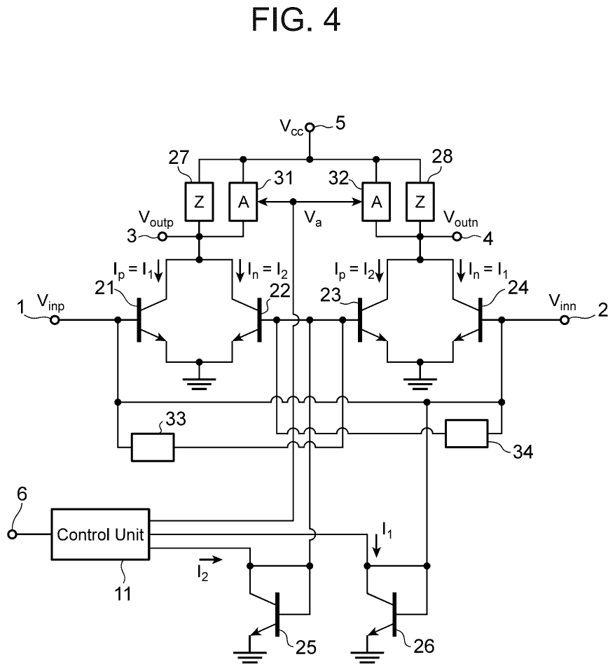

Next, a variable gain amplifier according to a third embodiment is explained with reference to FIG. 4. The variable gain amplifier according to the third embodiment is different from the variable gain amplifier according to the first embodiment in that variable impedance circuits are disposed differently. Other components in the variable gain amplifier according to the third embodiment are similar, the components that are similar to those in the first embodiment are given identical reference signs, and explanations thereof are omitted.

FIG. 4 is a circuit diagram illustrating the variable gain amplifier according to the third embodiment. As illustrated in FIG. 4, the variable gain amplifier according to the third embodiment includes variable impedance elements 31 and 32 as variable impedance circuits. The variable impedance element 31 is connected between both of the collector terminal of a transistor 21 and the collector terminal of a transistor 22 and a power supply terminal 5 in such a manner that the variable impedance element 31 is disposed in parallel with a load 27. In other words, the variable impedance element 31 is connected between an RF signal in-phase output terminal 3 and the power supply terminal 5 such that the variable impedance element 31 is disposed in parallel with the load 27. In addition, the variable impedance element 32 is connected between both of the collector terminal of a transistor 23 and the collector terminal of a transistor 24 and the power supply terminal 5 in such a manner that the variable impedance element 32 is disposed in parallel with a load 28. In other words, the variable impedance element 32 is connected between an RF signal antiphase output terminal 4 and the power supply terminal 5 in such a manner that the variable impedance element 32 is disposed in parallel with the load 28.

By arranging the variable impedance elements 31 and 32 in this manner, Z in Formula (1) representing the gain G of the variable gain amplifier according to the first embodiment can be replaced with Z+ΔA, and the gain G of the variable gain amplifier according to the first embodiment is represented by the following Formula (10).

$$G ( {I}_{p} - {I}_{n} , {V}_{a} ) = - \frac{2 ( Z + j Δ A ( {V}_{a} ) ) q}{kT} ( {I}_{1} - {I}_{2} ) \cdot \frac{\frac{2}{{r}_{π}} - j ω ( {C}_{π} ( 0 ) )}{\frac{4}{{r}_{π}} + j ωΔ {C}_{i n} ( \vert {I}_{1} - {I}_{2} \vert )} \qquad ( 10 )$$

In addition, in the third embodiment, a passing phase change Δϕ at the time when a control unit 11 changes a bias current I₁ and a current I₂ on the basis of set gain information is represented by the following Formula (11).

$$Δφ = - {tan}^{- 1} \frac{\{ 4 Δ A ( {V}_{a} ) - Z {r}_{π} Δ {C}_{i n} ( \vert {I}_{1} - {I}_{2} \vert ) \}}{4 Z Δ {C}_{i n} ( \vert {I}_{1} - {I}_{2} \vert ) ω} \qquad ( 11 )$$

Here, as illustrated by the following Formula (12), by the control unit 11 controlling an imaginary part component ΔA of the variable impedance elements, it is possible to keep the passing phase constant.

$$Δ A ( {V}_{a} ) = \frac{{Zr}_{π} Δ {C}_{i n} ( \vert {I}_{1} - {I}_{2} \vert )}{4} = \frac{{Zr}_{π} τ q Δ ( \vert {I}_{1} - {I}_{2} \vert )}{4 kT} \qquad ( 12 )$$

As mentioned above, the variable gain amplifier according to the third embodiment is a variable gain differential amplifier that changes the in-phase/antiphase current distribution, and controls a gain using a current difference. By using the control unit 11 to change variable impedance elements installed on the output side on the basis of the absolute value of the in-phase/antiphase current distribution using reverse characteristics, it is possible to keep the imaginary part of the input impedance constant, and also it is possible to cancel temperature characteristics. Thereby, the variable gain amplifier according to the third embodiment can reduce changes of the passing phase at the time when a gain is changed, and can reduce changes of the passing phase when temperature has changed.

Note that whereas, in the variable gain amplifier according to the third embodiment, the variable impedance element 31 is connected between the RF signal in-phase output terminal 3 and the power supply terminal 5 in such a manner that the variable impedance element 31 is disposed in parallel with the load 27, and the variable impedance element 32 is connected between the RF signal antiphase output terminal 4 and the power supply terminal 5 in such a manner that the variable impedance element 32 is disposed in parallel with the load 28, this is not the sole example. It is sufficient if the variable impedance element 31 is connected between one of the power supply terminal 5 and a ground terminal and the RF signal in-phase output terminal 3 in such a manner that the variable impedance element 31 is disposed in parallel with the load 27, and the variable impedance element 32 is connected between one of the power supply terminal 5 and the ground terminal and the RF signal antiphase output terminal 4 in such a manner that the variable impedance element 32 is disposed in parallel with the load 28. For example, the variable impedance element 31 may be connected between the ground terminal and the RF signal in-phase output terminal 3 in such a manner that the variable impedance element 31 is disposed in parallel with the load 27, and the variable impedance element 32 may be connected between the ground terminal and the RF signal antiphase output terminal 4 in such a manner that the variable impedance element 32 is disposed in parallel with the load 28.

### Fourth Embodiment

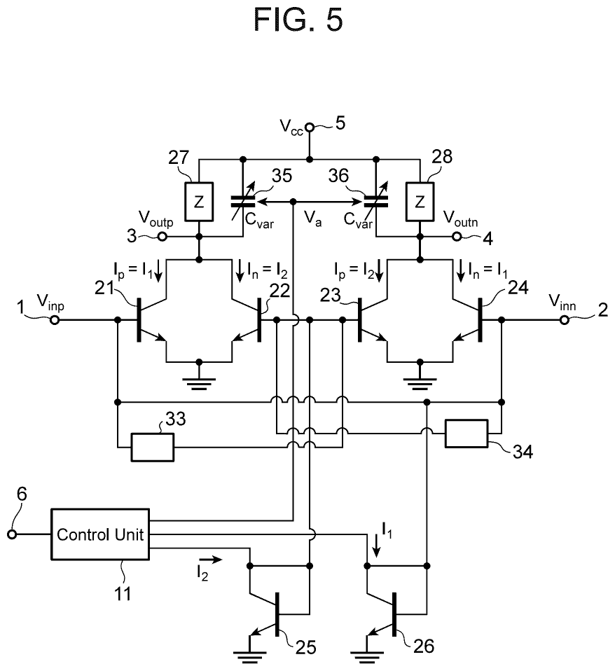

Next, a variable gain amplifier according to a fourth embodiment is explained with reference to FIG. 5. The variable gain amplifier according to the fourth embodiment is different from the variable gain amplifier according to the third embodiment in that the variable gain amplifier according to the fourth embodiment uses varactor elements as variable impedance circuits. Other components in the variable gain amplifier according to the fourth embodiment are similar, the components that are similar to those in the third embodiment are given identical reference signs, and explanations thereof are omitted.

FIG. 5 is a circuit diagram illustrating the variable gain amplifier according to the fourth embodiment. As illustrated in FIG. 5, instead of the variable impedance elements 31 and 32 of the variable gain amplifier according to the third embodiment, the variable gain amplifier according to the fourth embodiment uses varactor elements 35 and 36 as variable impedance circuits. Assuming that an amount of change due to Vₐ of the varactor elements 35 and 36 arranged in parallel with loads 27 and 28 is ΔCᵥₐᵣ, a gain G of the variable gain amplifier according to the fourth embodiment is represented by the following Formula (13).

$$G ( {I}_{p} - {I}_{n} , {V}_{a} ) = - \frac{2 ( Z + j Δ {C}_{va r} ( {V}_{a} ) ) q}{k T} ( {I}_{1} - {I}_{2} ) \cdot \frac{\frac{2}{{r}_{π}} - j ω ( {C}_{π} ( 0 ) )}{\frac{4}{{r}_{π}} + j ωΔ {C}_{i n} ( \vert {I}_{1} - {I}_{2} \vert )} \qquad ( 13 )$$

In addition, in the fourth embodiment, a passing phase change Δϕ at the time when a control unit 11 changes a bias current I₁ and a current I₂ on the basis of set gain information is represented by the following Formula (14).

$$Δφ = - {tan}^{- 1} \frac{\{ 4 Δ {C}_{v ar} ( {V}_{a} ) - {Zr}_{π} Δ {C}_{i n} ( \vert {I}_{1} - {I}_{2} \vert ) \}}{4 Z Δ {C}_{i n} ( \vert {I}_{1} - {I}_{2} \vert ) ω} \qquad ( 14 )$$

Here, as illustrated by the following Formula (15), by the control unit 11 controlling ΔCᵥₐᵣ of the varactor elements, it is possible to keep the passing phase constant.

$$Δ {C}_{v ar} ( {V}_{a} ) = \frac{{Zr}_{π} Δ {C}_{i n} ( \vert {I}_{1} - {I}_{2} \vert )}{4} = \frac{{Zr}_{π} τ q Δ ( \vert {I}_{1} - {I}_{2} \vert )}{4 kT} \qquad ( 15 )$$

At this time, the control unit 11 outputs the output voltage Vₐ as illustrated in the following Formula (16) for the current difference I₁−I₂.

$${V}_{a} = Δ {C}_{v ar}^{- 1} ( \frac{Z {r}_{π} τ q Δ ( \vert {I}_{1} - {I}_{2} \vert )}{4 k T} ) \qquad ( 16 )$$

As mentioned above, the variable gain amplifier according to the fourth embodiment is a variable gain differential amplifier that changes the in-phase/antiphase current distribution, and controls a gain using a current difference. By using the control unit 11 to change varactor capacitances installed on the output side on the basis of the absolute value of the in-phase/antiphase current distribution using reverse characteristics, it is possible to keep the imaginary part of the passing gain in gain control constant, and also it is possible to cancel temperature characteristics. Thereby, the variable gain amplifier according to the fourth embodiment can reduce changes of the passing phase at the time when a gain is changed, and can reduce changes of the passing phase when temperature has changed.

Note that whereas, in the variable gain amplifier according to the fourth embodiment, the varactor element 35 is connected between an RF signal in-phase output terminal 3 and a power supply terminal 5 in such a manner that the varactor element 35 is disposed in parallel with the load 27, and the varactor element 36 is connected between an RF signal antiphase output terminal 4 and the power supply terminal 5 in such a manner that the varactor element 36 is disposed in parallel with the load 28, this is not the sole example. It is sufficient if the varactor element 35 is connected between one of the power supply terminal 5 and a ground terminal and the RF signal in-phase output terminal 3 in such a manner that the varactor element 35 is disposed in parallel with the load 27, and the varactor element 36 is connected between one of the power supply terminal 5 and the ground terminal and the RF signal antiphase output terminal 4 in such a manner that the varactor element 36 is disposed in parallel with the load 28. For example, the varactor element 35 may be connected between the ground terminal and the RF signal in-phase output terminal 3 in such a manner that the varactor element 35 is disposed in parallel with the load 27, and the varactor element 36 may be connected between the ground terminal and the RF signal antiphase output terminal 4 in such a manner that the varactor element 36 is disposed in parallel with the load 28.

### Fifth Embodiment

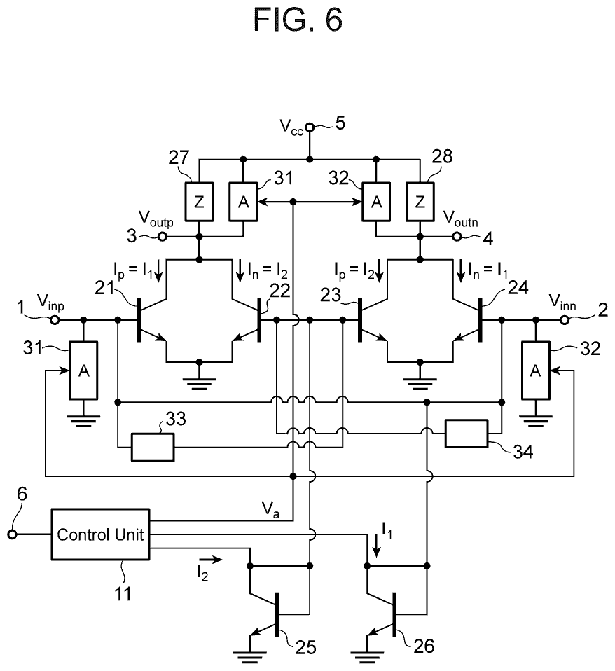

Next, a variable gain amplifier according to a fifth embodiment is explained with reference to FIG. 6. The variable gain amplifier according to the fifth embodiment is different from the variable gain amplifier according to the first embodiment in that variable impedance circuits are disposed differently. Other components in the variable gain amplifier according to the fifth embodiment are similar, the components that are similar to those in the first embodiment are given identical reference signs, and explanations thereof are omitted.

FIG. 6 is a circuit diagram illustrating the variable gain amplifier according to the fifth embodiment. As illustrated in FIG. 6, the variable gain amplifier according to the fifth embodiment additionally includes variable impedance elements 31 and 32 in addition to the variable impedance elements 31 and 32 included in the variable gain amplifier according to the first embodiment. The additional variable impedance element 31 as the third variable impedance circuit is connected between both of the collector terminal of a transistor 21 and the collector terminal of a transistor 22 and a power supply terminal 5 in such a manner that the additional variable impedance element 31 is disposed in parallel with a load 27 similarly to the variable impedance element 31 of the variable gain amplifier according to the third embodiment. In addition, the additional variable impedance element 32 as the fourth variable impedance circuit is connected between both of the collector terminal of a transistor 23 and the collector terminal of a transistor 24 and the power supply terminal 5 in such a manner that the additional variable impedance element 32 is disposed in parallel with a load 28 similarly to the variable impedance element 32 of the variable gain amplifier according to the third embodiment.

A gain G of the variable gain amplifier according to the fifth embodiment in which the variable impedance elements 31, 31, 32, and 32 are connected in this manner is represented by the following Formula (17).

$$G ( {I}_{p} - {I}_{n} , {V}_{a} ) = - \frac{2 ( Z + j Δ A ( {V}_{a} ) ) q}{kT} ( {I}_{1} - {I}_{2} ) \cdot \frac{\frac{2}{{r}_{π}} - j ω ( {C}_{π} ( 0 ) )}{\frac{4}{{r}_{π}} + j ωΔ {C}_{i n} ( \vert {I}_{1} - {I}_{2} \vert , {V}_{a} )} \qquad ( 17 )$$

In addition, in the fifth embodiment, a passing phase change Δϕ at the time when a control unit 11 changes a bias current I₁ and a current I₂ on the basis of set gain information is represented by the following Formula (18).

$$Δφ = - tan \frac{\{ 4 Δ A ( {V}_{a} ) - Z {r}_{π} ( Δ {C}_{π} ( \vert {I}_{1} - {I}_{2} \vert ) + Δ A ( {V}_{a} ) ) \}}{4 Z ( Δ {C}_{π} ( \vert {I}_{1} - {I}_{2} \vert ) + Δ A ( {V}_{a} ) ) ω} \qquad ( 18 )$$

Here, as illustrated by the following Formula (19), by the control unit 11 controlling ΔCᵥₐᵣ, it is possible to keep the passing phase constant.

$$Δ A ( {V}_{a} ) = \frac{{Zr}_{π} Δ {C}_{π} ( \vert {I}_{1} - {I}_{2} \vert )}{4 - {Zr}_{π}} = \frac{{Zr}_{π} τ q Δ ( \vert {I}_{1} - {I}_{2} \vert )}{( 4 - {Zr}_{π} ) kT} \qquad ( 19 )$$

At this time, the control unit 11 outputs the output voltage Vₐ as illustrated in the following Formula (20) for the current difference I₁−I₂.

$${V}_{a} = Δ {A}^{- 1} ( \frac{{Zr}_{π} τ q Δ ( \vert {I}_{1} - {I}_{2} \vert )}{( 4 - {Zr}_{π} ) kT} ) \qquad ( 20 )$$

As mentioned above, the variable gain amplifier according to the fifth embodiment is a variable gain differential amplifier that changes the in-phase/antiphase current distribution, and controls a gain using a current difference. By using the control unit 11 to change variable impedance elements installed on both the input side and the output side on the basis of the absolute value of the in-phase/antiphase current distribution using reverse characteristics, it is possible to keep the imaginary part of the passing gain in gain control constant, and also it is possible to cancel temperature characteristics. Thereby, the variable gain amplifier according to the fifth embodiment can reduce changes of the passing phase at the time when a gain is changed, and also can reduce changes of the passing phase when temperature has changed. In addition, by installing capacitances on both the input side and the output side, the range of ΔA increases. Accordingly, it is possible to cope with greater gain changes.

Note that whereas the variable gain amplifier according to the fifth embodiment includes the variable impedance elements 31, 31, 32, and 32 as variable impedance circuits, this is not the sole example. A variable gain amplifier may include varactor elements as variable impedance circuits instead of the variable impedance elements of the variable gain amplifier according to the fifth embodiment.

### Sixth Embodiment

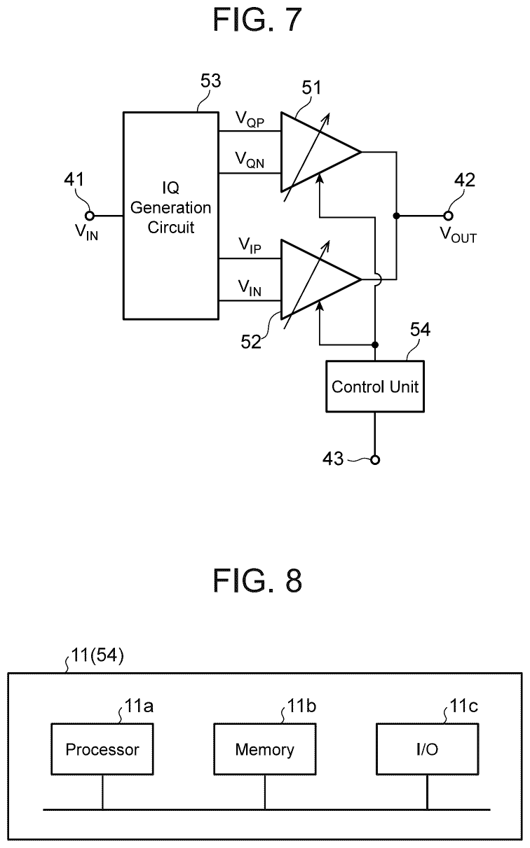

Next, a phase shifter according to a sixth embodiment is explained with reference to FIG. 7. The phase shifter according to the sixth embodiment includes variable gain amplifiers according to the first to fifth embodiments, and explanations of components that are similar to those in the first to fifth embodiments are omitted.

FIG. 7 is a circuit diagram illustrating the phase shifter according to the sixth embodiment. As illustrated in FIG. 7, the phase shifter according to the sixth embodiment is a vector-synthesis-type phase shifter including an input terminal 41, an output terminal 42, a passing phase setting terminal 43, variable gain amplifiers 51 and 52, an In-Phase, Quadrature-Phase (IQ) generation circuit 53, and a control unit 54. In addition, the variable gain amplifier 51 as the first variable gain amplifier and the variable gain amplifier 52 as the second variable gain amplifier are variable gain amplifiers according to any of the first to fifth embodiments.

The IQ generation circuit 53 converts an RF signal (input signal) input from the input terminal 41 into: an in-phase (In-Phase) signal (in-phase signal, first signal) which is a 0-degree component of the RF signal; an antiphase signal (second signal) of the RF signal; a differential signal (in-phase signal, third signal) which is a quadrature-phase (Quadrature-Phase) signal which is a 90-degree component of the RF signal; and an antiphase signal (fourth signal) of the quadrature-phase signal. In addition, the IQ generation circuit 53 outputs the first signal and the second signal to the variable gain amplifier 51, and outputs the third signal and the fourth signal to the variable gain amplifier 52.

A set gain G_{I} in the variable gain amplifier 51 and a set gain G_{Q} in the variable gain amplifier 52 are calculated on the basis of the following Formula (21) at the control unit 54 on the basis of a phase shift amount θ input from the passing phase setting terminal 43, and values obtained thereby are input to the variable gain amplifiers 51 and 52 as set gain information.

$${G}_{Q} = cos θ , {G}_{I} = sin θ \qquad ( 21 )$$

On the basis of the input set gain information, the variable gain amplifier 51 adjusts and outputs the amplitudes of the first signal and the second signal. On the basis of the input set gain information, the variable gain amplifier 52 adjusts and outputs the amplitudes of the third signal and the fourth signal. The signals output by the variable gain amplifier 51 and the signals output by the variable gain amplifier 52 are synthesized again, and output from the output terminal 42.

The phase shifter according to the sixth embodiment does not experience a passing phase change in the set gains G_{Q} and G_{I} based on phase shift settings. Accordingly, it is not necessary for the control unit to keep correction tables therefor. In addition, similarly, the phase shifter according to the sixth embodiment does not experience a passing phase change in response to temperature changes. Accordingly, it is not necessary for the control unit to keep correction tables therefor. Thereby, it is possible to implement the phase shifter according to the sixth embodiment using a control unit with a small memory. Accordingly, it is possible to implement a small-sized phase shifter and to implement a radar device such as a small-sized active electronically scanned array (AESA, active electronically scanned array) antenna or a phased array antenna including the phase shifter.

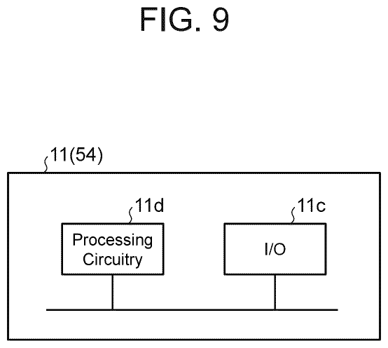

Next, the hardware configuration of the control units 11 according to the first to sixth embodiments, and the hardware configuration of the control unit 54 according to the sixth embodiment are explained with reference to FIG. 8 and FIG. 9. FIG. 8 is a block diagram illustrating an example of the hardware configuration of the control unit 11 according to the first embodiment, and FIG. 9 is a block diagram illustrating an example of the hardware configuration of the control unit 11 according to the first embodiment different from FIG. 8. For example, as illustrated in FIG. 8, the control unit 11 has a processor 11a, a memory 11b, and an I/O port 11c, and is configured in such a manner that the processor 11a reads out and executes programs stored on the memory 11b. For example, the memory 11b may be a non-volatile or volatile semiconductor memory such as a RAM, a ROM, a flash memory, an EPROM, or an EEPROM. In addition, the memory 11b may be a magnetic disk, a flexible disc, an optical disc, a compact disc, a mini disc, a DVD, or the like. Furthermore, the memory 11b may be an HDD or an SSD.

In addition, for example, as illustrated in FIG. 6, the control unit 11 has processing circuitry 11d and the I/O port 11c, which are dedicated hardware. For example, the processing circuitry 11d is configured using a single circuit, a composite circuit, a programmed processor, a parallel-programmed processor, a system Large-Scale Integration (LSI), an Application Specific Integrated Circuit (ASIC), a Field Programmable Gate Array (FPGA), or a combination of these. Respective functions of the control unit 11 are implemented by the processor 11a or the processing circuitry 11d, which is dedicated hardware, executing programs which are software, firmware, or combinations of software and firmware.

Note that the hardware configurations of the control units 11 according to the second to sixth embodiments, and the hardware configuration of the control unit 54 according to the sixth embodiment are similar to that of the control unit 11 according to the first embodiment, and accordingly explanations thereof are omitted.

Note that, in the present disclosure, any combination of the embodiments, modification of any component in each of the embodiments, or omission of any component in each of the embodiments is possible.

### INDUSTRIAL APPLICABILITY

The variable gain amplifiers according to the present disclosure can be used for beamforming in a phased array antenna, for example.

Hereinafter, several aspects of the present disclosure are described collectively as supplementary notes.

### (Supplementary Note 1)

A variable gain amplifier including:
a first input terminal;
a second input terminal;
a power supply terminal;
a ground terminal;
a first transistor having a base terminal that is connected to the first input terminal, and having an emitter terminal connected to the ground terminal;
a second transistor having a base terminal that is connected to the second input terminal, having an emitter terminal that is connected to the ground terminal, and having a collector terminal that is connected to a collector terminal of the first transistor;
a third transistor having a base terminal that is connected to the first input terminal, and having an emitter terminal that is connected to the ground terminal;
a fourth transistor having a base terminal that is connected to the second input terminal, having an emitter terminal that is connected to the ground terminal, and having a collector terminal that is connected to a collector terminal of the third transistor;
a first reference current transistor that is diode-connected, and is connected to the first transistor and the fourth transistor in such a manner that the first transistor and the fourth transistor form a current mirror;
a second reference current transistor that is diode-connected, and is connected to the second transistor and the third transistor in such a manner that the second transistor and the third transistor form a current mirror;
a first load connected between both of the collector terminal of the first transistor and the collector terminal of the second transistor and the power supply terminal;
a second load connected between both of the collector terminal of the third transistor and the collector terminal of the fourth transistor and the power supply terminal;
a first output terminal connected to the first load;
a second output terminal connected to the second load;
a first variable impedance circuit connected between one of the power supply terminal and the ground terminal and one of the first input terminal and the first output terminal;
a second variable impedance circuit connected between one of the power supply terminal and the ground terminal and one of the second input terminal and the second output terminal; and
a control unit to acquire set gain information related to a setting of a gain, and, on a basis of the set gain information, output a current to the first reference current transistor and the second reference current transistor in such a manner that a sum of a value of a current to the first reference current transistor and a value of a current to the second reference current transistor becomes constant, and output, to the first variable impedance circuit and the second variable impedance circuit, a voltage obtained by multiplying an absolute value of a difference between a value of a current to the first reference current transistor and a value of a current to the second reference current transistor by a coefficient, in which
on a basis of reception of an input of an in-phase signal by the first input terminal and reception of an input of an antiphase signal of the in-phase signal by the second input terminal, an in-phase signal amplified on a basis of the set gain information is output from the first output terminal, and an antiphase signal amplified on a basis of the set gain information is output from the second output terminal.

### (Supplementary Note 2)

The variable gain amplifier according to supplementary note 1, including:
a third variable impedance circuit connected between the first output terminal and one of the power supply terminal and the ground terminal; and
a fourth variable impedance circuit connected between the second output terminal and one of the power supply terminal and the ground terminal.

### (Supplementary Note 3)

The variable gain amplifier according to supplementary note 1, in which
the first variable impedance circuit is connected between one of the power supply terminal and the ground terminal and the first input terminal, and
the second variable impedance circuit is connected between one of the power supply terminal and the ground terminal and the second input terminal.

### (Supplementary Note 4)

The variable gain amplifier according to supplementary note 1, in which
the first variable impedance circuit is connected between one of the power supply terminal and the ground terminal and the first output terminal, and
the second variable impedance circuit is connected between one of the power supply terminal and the ground terminal and the second output terminal.

### (Supplementary Note 5)

A phase shifter including:
a first variable gain amplifier which is the variable gain amplifier according to any one of supplementary notes 1 to 4;
a second variable gain amplifier which is the variable gain amplifier according to any one of supplementary notes 1 to 4; and
an IQ generation circuit that outputs, on a basis of an input signal and to the first variable gain amplifier, a first signal which is an in-phase signal of the input signal, and a second signal which is an antiphase signal of the input signal, and outputs, on a basis of the input signal and to the second variable gain amplifier, a third signal which is a quadrature-phase signal of the input signal, and a fourth signal which is an antiphase signal of the quadrature-phase signal, in which
a signal output by the first variable gain amplifier on a basis of reception of inputs of the first signal and the second signal, and a signal output by the second variable gain amplifier on a basis of reception of inputs of the third signal and the fourth signal are synthesized and output.

### REFERENCE SIGNS LIST

1: RF signal in-phase input terminal (First input terminal), 2: RF signal antiphase input terminal (Second input terminal), 3: RF signal in-phase output terminal (First output terminal), 4: RF signal antiphase output terminal (Second output terminal), 5: Power supply terminal, 6: Amplitude control signal input terminal, 11: Control unit, 21: Transistor (First transistor), 22: Transistor (second transistor), 23: Transistor (Third transistor), 24: Transistor (Fourth transistor), 25: Transistor (Second reference current transistor), 26: Transistor (First reference current transistor), 27 and 28: Load, 31: Variable impedance element (First variable impedance circuit), 32: Variable impedance element (Second variable impedance circuit), 33 and 34: Coupling element, 35: Varactor element (First variable impedance circuit), 36: Varactor element (Second variable impedance circuit), 41: Input terminal, 42: Output terminal, 43: Passing Phase setting terminal, 51 and 52: Variable gain amplifier, 53: IQ Generation circuit, 54: Control unit

1. A variable gain amplifier comprising:
a first input terminal;
a second input terminal;
a power supply terminal;
a ground terminal;
a first transistor having a base terminal that is connected to the first input terminal, and having an emitter terminal connected to the ground terminal;
a second transistor having a base terminal that is connected to the second input terminal, having an emitter terminal that is connected to the ground terminal, and having a collector terminal that is connected to a collector terminal of the first transistor;
a third transistor having a base terminal that is connected to the first input terminal, and having an emitter terminal that is connected to the ground terminal;
a fourth transistor having a base terminal that is connected to the second input terminal, having an emitter terminal that is connected to the ground terminal, and having a collector terminal that is connected to a collector terminal of the third transistor;
a first reference current transistor that is diode-connected, and is connected to the first transistor and the fourth transistor in such a manner that the first transistor and the fourth transistor form a current mirror;
a second reference current transistor that is diode-connected, and is connected to the second transistor and the third transistor in such a manner that the second transistor and the third transistor form a current mirror;
a first load connected between both of the collector terminal of the first transistor and the collector terminal of the second transistor and the power supply terminal;
a second load connected between both of the collector terminal of the third transistor and the collector terminal of the fourth transistor and the power supply terminal;
a first output terminal connected to the first load;
a second output terminal connected to the second load;
a first variable impedance circuit connected between one of the power supply terminal and the ground terminal and one of the first input terminal and the first output terminal;
a second variable impedance circuit connected between one of the power supply terminal and the ground terminal and one of the second input terminal and the second output terminal; and
a processing circuitry to acquire set gain information related to a setting of a gain, and, on a basis of the set gain information, output a current to the first reference current transistor and the second reference current transistor in such a manner that a sum of a value of a current to the first reference current transistor and a value of a current to the second reference current transistor becomes constant, and output, to the first variable impedance circuit and the second variable impedance circuit, a voltage obtained by multiplying an absolute value of a difference between a value of a current to the first reference current transistor and a value of a current to the second reference current transistor by a coefficient,
wherein, on a basis of reception of an input of an in-phase signal by the first input terminal and reception of an input of an antiphase signal of the in-phase signal by the second input terminal, an in-phase signal amplified on a basis of the set gain information is output from the first output terminal, and an antiphase signal amplified on a basis of the set gain information is output from the second output terminal.

2. The variable gain amplifier according to claim 1, comprising:
a third variable impedance circuit connected between the first output terminal and one of the power supply terminal and the ground terminal; and
a fourth variable impedance circuit connected between the second output terminal and one of the power supply terminal and the ground terminal.

3. The variable gain amplifier according to claim 1, wherein
the first variable impedance circuit is connected between one of the power supply terminal and the ground terminal and the first input terminal, and
the second variable impedance circuit is connected between one of the power supply terminal and the ground terminal and the second input terminal.

4. The variable gain amplifier according to claim 1, wherein
the first variable impedance circuit is connected between one of the power supply terminal and the ground terminal and the first output terminal, and
the second variable impedance circuit is connected between one of the power supply terminal and the ground terminal and the second output terminal.

5. A phase shifter comprising:
a first variable gain amplifier which is the variable gain amplifier according to claim 1;
a second variable gain amplifier which is the variable gain amplifier according to claim 1; and
an IQ generation circuit that outputs, on a basis of an input signal and to the first variable gain amplifier, a first signal which is an in-phase signal of the input signal, and a second signal which is an antiphase signal of the input signal, and outputs, on a basis of the input signal and to the second variable gain amplifier, a third signal which is a quadrature-phase signal of the input signal, and a fourth signal which is an antiphase signal of the quadrature-phase signal, wherein
a signal output by the first variable gain amplifier on a basis of reception of inputs of the first signal and the second signal, and a signal output by the second variable gain amplifier on a basis of reception of inputs of the third signal and the fourth signal are synthesized and output.
